(19) United States
(12) Patent Application Publication
(10) Pub. No.: US 2018/0350539 A1
(43) Pub. Date: Dec. 6, 2018

(54) 360-DEGREE BLIND-ANGLE-FREE POSITION DETECTION MAGNETIC SENSOR

(71) Applicants: FOSHAN Yif Technologies Co., Ltd., Foshan, Guangdong (CN); CHUANDONG MAGNETIC ELECTRONICS CO., LTD, Foshan, Guangdong (CN)

(72) Inventors: Li Liu, Foshan, Guangdong (CN); KeWen LONG, Foshan, Guangdong (CN)

(21) Appl. No.: 15/772,502

(22) PCT Filed: Jan. 4, 2017
(86) PCT No.: PCT/CN2017/070117

§ 371 Date: Apr. 30, 2018

(30) Foreign Application Priority Data
Jan. 12, 2016 (CN) 201610018517.2

(51) Int. Cl. H01H 36/00; H03K 17/97

(52) U.S. Cl. CPC H01H 36/0033; H03K 2217/94068; H03K 17/97

(57) ABSTRACT

A 360-degree blind-angle-free position detection magnetic sensor comprising a hollow plastic box, wherein a hollow reed is transversely disposed in the plastic box, and damping springs are respectively disposed at the two ends of the hollow reed; the outer ends of the two damping springs are respectively fixedly connected with the inner walls of the two ends of the plastic box; the hollow reed is movably suspended in an inner chamber of the plastic box, and a conductive magnetic ring is sleeved on the hollow reed; a conductive column is disposed in the plastic box; the inner end of the conductive column penetrates into the hollow reed, and is matched with the hollow reed; lead wires that are electrically connected with the conductive column and the hollow reed are disposed on the plastic box.

### TECHNICAL FIELD OF THE INVENTION

The present invention relates to the technical field of magnetic proximity switches, and more particularly, to a 360-degree blind-angle-free position detection magnetic sensor.

### BACKGROUND OF THE INVENTION

A magnetic proximity switch is a proximity sensor that uses a magnetic element to detect the positional variation of nearby objects, which is capable of converting the non-electrical quantities or electromagnetic quantities into required electrical signals, thereby serving the purposes of controlling and measuring. In the field of robot application technologies, automatic navigation and position detection are crucial for intelligent control. Compared with commonly-used controllers, proximity switches possess incomparable advantages in positioning detection and execution control. The traditional magnetic proximity switches that achieve position sensing through magnetic field detection are mainly divided into a hall type, a magnetic-group type and a reed-switch type. As core magnetic sensitive elements are introduced from abroad, the production period is long and the cost is high. In robotics, the interrelation of automatic control equipment and intelligent equipment manufacturing, the position variance and motion sensing are very complicated. In the prior art, the external magnetic drive sensing usually uses linear control technology. In order to achieve the control mechanism of homo-polar repulsion and hetero-polar attraction, north and south of the external and internal magnetic poles must be clearly distinguished. As a result, the sensing and control system must be provided with several unique magnetic switches, resulting in a complex structure and a difficult manufacturing process. With the development of automation and intelligent control, products having a smaller and more compact structure have become the main stream. Thus, it's urgent for those skilled in this field to develop a novel magnetic sensor.

### SUMMARY OF THE INVENTION

The purpose of the present invention is to solve the shortcomings in the prior art by providing a 360-degree blind-angle-free position detection magnetic sensor, which has a compact structure and can be flexibly configured.

To achieve the above purpose, the present invention adopts the following technical solution:

A 360-degree blind-angle-free position detection magnetic sensor comprising a hollow plastic box, wherein a hollow reed is transversely disposed in the plastic box, and damping springs are respectively disposed at the two ends of the hollow reed; the outer ends of the two damping springs are respectively fixedly connected with the inner walls of the two ends of the plastic box; the hollow reed is movably suspended in an inner chamber of the plastic box, and a conductive magnetic ring is sleeved on the hollow reed; a conductive column is disposed in the plastic box; the inner end of the conductive column penetrates into the hollow reed, and is matched with the hollow reed; lead wires that are electrically connected with the conductive column and the hollow reed are disposed on the plastic box.

In another aspect of the present invention, a suspension bracket is disposed in the plastic box, and the hollow reed is movably suspended in the suspension bracket. Locking pieces are matched with the conductive magnetic ring and are disposed on the outer edges of the two ends of the hollow reed. The inner ends of the two damping springs are respectively sleeved on the corresponding ends of the hollow reed, and are electrically connected with the hollow reed. Fixing bosses are disposed on the inner side walls of the two ends of the suspension bracket, and the outer ends of the two damping springs are respectively sleeved on the corresponding fixing bosses.

In another aspect of the present invention, a fixing hole that extends throughout the fixing boss is formed in the side wall of the left end of the suspension bracket. A limiting ring is disposed at the outer end of the conductive column. The conductive column is inserted into the fixing hole, and is connected with the fixing hole in a matching manner. The inner end of the conductive column penetrates through the hollow reed, and is matched with the hollow reed.

In another aspect of the present invention, a left conductive sheet is disposed between the left side wall of the plastic box and the suspension bracket, and a riveting hole is formed in one end of the left conductive sheet. The outer end of the conductive column penetrates through the riveting hole, and is electrically connected with the left conductive sheet. The other end of the left conductive sheet is provided with a clamping plate. The corresponding lead wire on the plastic box penetrates into the clamping plate, and is soldered on the left conductive sheet.

In another aspect of the present invention, a right conductive sheet is disposed between the right side wall of the plastic box and the suspension bracket. The inner end of the right conductive sheet penetrates through the suspension bracket, and is electrically connected with the damping spring at the right end. The outer end of the right conductive sheet is electrically connected with the corresponding lead wire on the plastic box. A limiting mechanism is disposed between the outer end of the right conductive sheet and the plastic box.

In another aspect of the present invention, the limiting mechanism comprises a strip-shaped protruding block, which is disposed on a bottom plate of the plastic box. The two sides of the outer end of the right conductive sheet are respectively provided with a limiting hinge, and a positioning opening is formed in the lower end of the limiting hinge. The positioning opening is clamped on the strip-shaped protruding block, and is in interference fit with the strip-shaped protruding block.

In another aspect of the present invention, the lead wire on the right side wall of the plastic box is disposed between the two limiting hinges in a penetrating manner, and the lead wire is electrically connected with the right conductive sheet.

In another aspect of the present invention, the front surface of the plastic box is an opening provided with sealant. The suspension bracket is a frame structure with an opening in the front surface. An insulating spacer is disposed between the opening of the suspension bracket and the sealant.

In another aspect of the present invention, the two ends of the insulating spacer are respectively provided with a buckle plate. The insulating spacer is disposed on the front surface opening of the suspension bracket, and the two buckle plates are respectively buckled at the two ends of the suspension bracket. A socket matched with the right conductive sheet is disposed on the buckle plate at the right end.

In another aspect of the present invention, the conductive magnetic ring is a hard magnetic ring possessing a single polarity on its outer periphery.

Compared with the prior art, the present invention has the following advantages:

As the conductive magnetic ring of the present invention possesses a single polarity on its outer periphery, it's unnecessary to select the polarity of the outer magnetic pole that needs to be matched with the conductive magnetic ring. Due to this design, the attraction or repulsion between the magnetic poles can be achieved. Furthermore, the conductive magnetic ring and the hollow reed are suspended in the suspension bracket, and the damping springs constantly provide a supporting force to the two ends of the hollow reed. When the external magnetic pole approaches the hollow reed from any angle, the motions of the hollow reed can be triggered. Thus, the switching on/off between the hollow reed and the conductive column can be realized. The present invention breaks the limitation of detecting angle and solves the polarity matching problem of the traditional sensors. Thus, robots' motion sensing can be more flexible, and the number of sensors can be reduced.

### BRIEF DESCRIPTION OF THE DRAWINGS

To clearly expound the technical solution of the present invention, the drawings and embodiments are hereinafter combined to illustrate the present invention. Obviously, the drawings are merely some embodiments of the present invention and those skilled in the art can associate themselves with other drawings without paying creative labor.

FIG. 1 is an explosive view the present invention;

FIG. 2 is a structural diagram illustrating the internal assembly structure of the present invention.

Marking Instructions of the Drawings:

1 Plastic Box, 2 Conductive Magnetic Ring, 3 Conductive Column, 4 Right Conductive Sheet, 11 Suspension Bracket; 12 Fixing Boss, 13 Fixing Hole, 14 Strip-shaped Protruding Block, 15 Sealant; 16 Insulating Spacer, 17 Buckle Plate, 18 Socket, 19 Lead Wire, 21 Hollow Reed, 22 Damping Spring, 23 Locking Piece, 31 Limiting Ring; 32 Left Conductive Sheet, 33 Riveting Hole, 34 Clamping Plate, 41 Contact Piece, 42 Limiting Hinge, 43 Positioning Opening

### DETAILED DESCRIPTION OF THE INVENTION

Drawings and detailed embodiments are combined hereinafter to elaborate the technical principles of the present invention.

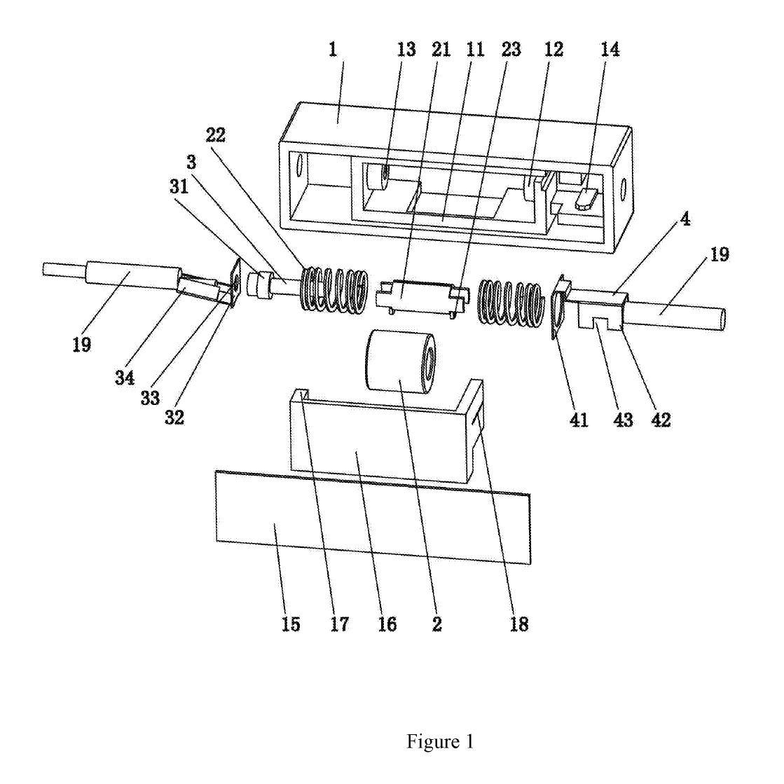

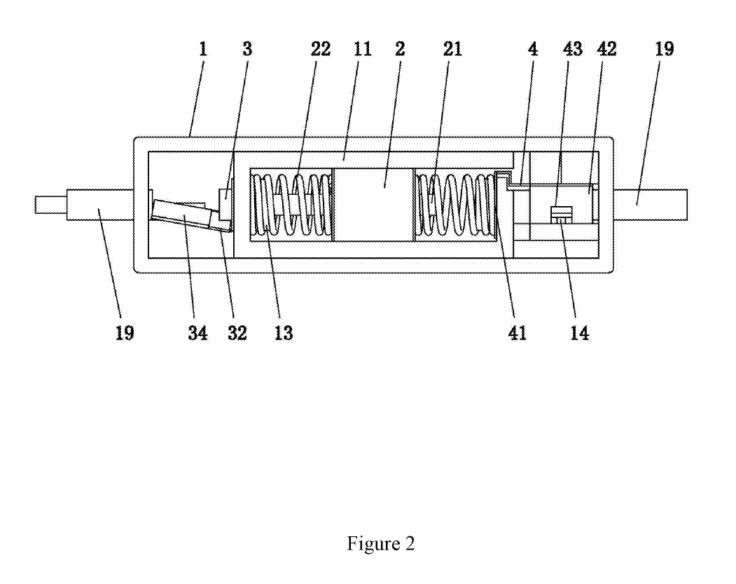

As shown in FIGS. 1-2, the 360-degree blind-angle-free position detection magnetic sensor of the present invention comprises a hollow plastic box 1, wherein a hollow reed 21 is transversely disposed in the plastic box 1, and damping springs 22 are respectively disposed at the two ends of the hollow reed 21. The outer ends of the two damping springs 22 are respectively fixedly connected with the inner walls of the two ends of the plastic box 1. The hollow reed 21 is movably suspended in an inner chamber of the plastic box 1, and a conductive magnetic ring 2 possessing a single polarity on its outer periphery is sleeved on the hollow reed 21. The conductive magnetic ring 2 possessing a single polarity on the outer periphery can be paired with an external magnetic pole or a ferromagnetic body having any polarity, thereby achieving an attracting or repulsing motion. Thus, the hollow reed 21 is triggered to achieve switch on/off, enabling the sensor to output corresponding control signals. The two damping springs 22 respectively support the hollow reed 21 and the conductive magnetic ring 2 from the two ends. In this way, the two damping springs 22, which are suspended in the inner chamber of the plastic box 1, are capable of achieving corresponding motions when the external magnetic pole or the ferromagnetic body having any polarity approaches. When the external magnetic pole or the ferromagnetic body is far away from the magnetic field, the damping springs 22 provide a reset force, which enables the hollow reed 21 and the conductive magnetic ring 22 to return to their initial positions. A conductive column 3 is disposed in the plastic box 1. The inner end of the conductive column 3 penetrates into the hollow reed 21, and is matched with the hollow reed 21. When the conductive magnetic ring 22 repels or attracts the external magnetic pole or the ferromagnetic body, the hollow reed 21 is propelled to abut against the conductive column 3. Thus, the hollow reed 21 is electrically connected with the conductive column 3, and the sensor outputs a switching on/off signal accordingly. Lead wires 19 that are electrically connected with the conductive column 3 and the hollow reed 21 are disposed on the plastic box 1.

A suspension bracket 11 is disposed in the plastic box 1, and the hollow reed 21 is movably suspended in the suspension bracket 11. Locking pieces 23 that are matched with the conductive magnetic ring 2 are disposed on the outer edges of the two ends of the hollow reed 21. The inner ends of the two damping springs 22 are respectively sleeved on the corresponding ends of the hollow reed 21, and are electrically connected with the hollow reed 21. Two fixing bosses 12 are disposed on the inner side walls of the two ends of the suspension bracket 11, and the outer ends of the two damping springs 22 are respectively sleeved on the corresponding fixing bosses 12. The suspension bracket 11 separates the inner chamber of the plastic box 1 into a left accommodating chamber, a middle accommodating chamber and a right accommodating chamber. The hollow reed 21 and the conductive magnetic ring 2 are suspended in the middle accommodating chamber in the suspension bracket 11. The damping springs 22 that are sleeved on the fixing bosses 12 are connected to the suspension bracket 11, and the damping springs 22 impose a pressure on the hollow reed 21, enabling the hollow reed 21 to be located at the stereo-center of the suspension bracket 11 in the initial state. At this point, the distance between the outer edge of the conductive magnetic ring 2 and the upper, lower, front and rear inner walls of the suspension bracket 11 is the travel limit of the conductive magnetic ring 2. Thus, the 360-degree blind-angle-free detection and the output of motion signals can be achieved.

A fixing hole 13 that extends throughout the fixing boss 12 is formed in the side wall of the left end of the suspension bracket 11, and the fixing hole 13 is a stepped hole with a large exterior and a small interior. A limiting ring 31 is disposed at the outer end of the conductive column 3. The conductive column 3 is inserted into the fixing hole 13, and is connected with the fixing hole in a matching manner. The inner end of the conductive column 3 penetrates through the hollow reed 21, and is matched with the hollow reed 21. The conductive column 3 penetrates through the fixing hole 13, and the inner end of the conductive column 3 is located on the center line of the inner hole of the hollow reed 21 (in a normal state, the conductive column is suspended in the reed). Thus, when the hollow reed 21 moves along the radial direction, the conductive column 3 is in contact with the hollow reed 21, and is electrically connected with the hollow reed 21.

A left conductive sheet 32 is disposed between the left side wall of the plastic box 1 and the suspension bracket 11, and a riveting hole 33 is formed in one end of the left conductive sheet 32. The outer end of the conductive column 3 penetrates through the riveting hole 33, and is electrically connected with the left conductive sheet 32. The other end of the left conductive sheet 32 is provided with a clamping plate 34. The corresponding lead wire 19 on the plastic box 1 penetrates into the clamping plate 34, and is soldered on the left conductive sheet 32. Preferably, an independent space is formed between the suspension bracket 11 and the left side wall of the plastic box 1. The conductive column penetrates through the fixing hole 13, and is in interference fit with the fixing hole. Moreover, the inner chamber of the plastic box 1 on the left side of the suspension bracket 11 can be filled with insulating glue, thus improving the electrical safety and the insulation stability of the sensor.

A right conductive sheet 4 is disposed between the right side wall of the plastic box 1 and the suspension bracket 11. The inner end of the right conductive sheet 4 penetrates through the suspension bracket 11, and is electrically connected with the damping spring 22 at the right end. The outer end of the right conductive sheet 4 is electrically connected with the corresponding lead wire 19 on the plastic box 1. A limiting mechanism is disposed between the outer end of the right conductive sheet 4 and the plastic box 1. Preferably, an assembly port is formed in the side wall of the right end of the suspension bracket 11, and the right conductive sheet 4 is inserted into the assembly port. A contact piece 41 that is electrically connected with the damping spring 22 is disposed at the inner end of the right conductive sheet 4. Preferably, the accommodating chamber of the plastic box 1 that is located on the right side of the suspension bracket 11 is an independent space, which can be filled with insulating glue for improving the electrical safety and the insulation stability of the magnetic sensor.

The aforesaid limiting mechanism comprises a strip-shaped protruding block 14, which is disposed on a bottom plate of the plastic box 1. The two sides of the outer end of the right conductive sheet 4 are respectively provided with a limiting hinge, and a positioning opening 43 is formed in the lower end of the limiting hinge 42. The positioning opening 43 is clamped on the strip-shaped protruding block 14, and is in interference fit with the strip-shaped protruding block 14. The plastic box 1 is provided with a top plate. The top plate and the bottom plate of the plastic box 1 are respectively provided with a height adjusting block. The right conductive sheet 4 is disposed between the upper height adjusting block and the lower height adjusting block in a penetrating manner, and is connected with the upper height adjusting block and the lower height adjusting block. The height adjusting blocks enable the right conductive sheet 4 and the assembly port of the suspension bracket 11 to be positioned at equal height. The strip-shaped protruding block 14 is disposed on the lower height adjusting block, and is matched with the positioning opening 43. Thus, the transverse displacement of the right conductive sheet 4 can be avoided, and the stability of electric connection can be guaranteed.

The lead wire 19 on the right side wall of the plastic box 1 is disposed between the two limiting hinges 42 in a penetrating manner, and the lead wire 19 is electrically connected with the right conductive sheet 4. A channel formed between the limiting hinges 42 is capable of facilitating the penetration and soldering of the lead wire 19. After being soldered, the right conductive sheet 4 and the lead wire 19 can be conveniently assembled, greatly improving the production efficiency.

The front surface of the plastic box 1 is an opening, on which is provided with sealant. The left and right accommodating chambers of plastic box 1 are respectively filled with sealant 15. The suspension bracket 11 is a frame structure with an opening in the front surface. An insulating spacer 16 is disposed between the opening of the suspension bracket 11 and the sealant 15. The opening in the front surface of the plastic box 1 is an assembly port, which can be sealed by sealants such as epoxy resin, silicone adhesive or glue 702 after the assembly process is completed.

The two ends of the insulating spacer 16 are respectively provided with a buckle plate 17. The insulating spacer 16 is disposed on the front surface opening of the suspension bracket 11, and the two buckle plates 17 are respectively buckled at the two ends of the suspension bracket 11. A socket 18 matched with the right conductive sheet 4 is disposed on the buckle plate 17 at the right end, and the insulating spacer 16 is a packaging cover plate for the inner components of the suspension bracket 11. The distance between the insulating spacer 16 and the inner wall of the plastic box 1 is the longitudinal travel limit of the conductive magnetic ring 2. After the buckle plate 17 at the right end is meshed with the right conductive sheet 4, the assembly port in the suspension bracket 11 can be sealed, allowing the insulating glue to be conveniently poured into the accommodating chamber on the right side of the plastic box 1.

As the conductive magnetic ring is a hard magnetic ring possessing a single polarity on its outer periphery, it's unnecessary to select the polarity of the outer magnetic pole that needs to be matched with the conductive magnetic ring of the present invention. Due to this design, the attraction or repulsion between the magnetic poles can be achieved.

The description of above embodiments allows those skilled in the art to realize or use the present invention. Without departing from the spirit and essence of the present invention, those skilled in the art can combine, change or modify correspondingly according to the present invention. Therefore, the protective range of the present invention should not be limited to the embodiments above but conform to the widest protective range which is consistent with the principles and innovative characteristics of the present invention. Although some special terms are used in the description of the present invention, the scope of the invention should not necessarily be limited by this description. The scope of the present invention is defined by the claims.

1. A 360-degree blind-angle-free position detection magnetic sensor, comprising:
a hollow plastic box, wherein a hollow reed is transversely disposed in the plastic box, and damping springs are respectively disposed at the two ends of the hollow reed, wherein the outer ends of the two damping springs are respectively fixedly connected with the inner walls of the two ends of the plastic box, wherein the hollow reed is movably suspended in an inner chamber of the plastic box, and a conductive magnetic ring is sleeved on the hollow reed, wherein a conductive column is disposed in the plastic box, wherein the inner end of the conductive column penetrates into the hollow reed, and is matched with the hollow reed, wherein lead wires that are electrically connected with the conductive column and the hollow reed are disposed on the plastic box.

2. The 360-degree blind-angle-free position detection magnetic sensor of claim 1, wherein a suspension bracket is disposed in the plastic box, and the hollow reed is movably suspended in the suspension bracket, wherein locking pieces that are matched with the conductive magnetic ring are disposed on the outer edges of the two ends of the hollow reed, wherein the inner ends of the two damping springs are respectively sleeved on the corresponding ends of the hollow reed, and are electrically connected with the hollow reed, wherein fixing bosses are disposed on the inner side walls of the two ends of the suspension bracket, and the outer ends of the two damping springs are respectively sleeved on the corresponding fixing bosses.

3. The 360-degree blind-angle-free position detection magnetic sensor of claim 2, wherein a fixing hole that extends throughout the fixing boss is formed in the side wall of the left end of the suspension bracket, wherein a limiting ring is disposed at the outer end of the conductive column, wherein the conductive column is inserted into the fixing hole, and is connected with the fixing hole in a matching manner, wherein the inner end of the conductive column penetrates through the hollow reed, and is matched with the hollow reed.

4. The 360-degree blind-angle-free position detection magnetic sensor of claim 3, wherein a left conductive sheet is disposed between the left side wall of the plastic box and the suspension bracket, and a riveting hole is formed in one end of the left conductive sheet, wherein the outer end of the conductive column penetrates through the riveting hole, and is electrically connected with the left conductive sheet, wherein the other end of the left conductive sheet is provided with a clamping plate, wherein the corresponding lead wire on the plastic box penetrates into the clamping plate, and is soldered on the left conductive sheet.

5. The 360-degree blind-angle-free position detection magnetic sensor of claim 2, wherein a right conductive sheet is disposed between the right side wall of the plastic box and the suspension bracket, wherein the inner end of the right conductive sheet penetrates through the suspension bracket, and is electrically connected with the damping spring at the right end, wherein the outer end of the right conductive sheet is electrically connected with the corresponding lead wire on the plastic box, wherein a limiting mechanism is disposed between the outer end of the right conductive sheet and the plastic box.

6. The 360-degree blind-angle-free position detection magnetic sensor of claim 5, wherein the limiting mechanism comprises a strip-shaped protruding block, which is disposed on a bottom plate of the plastic box, wherein the two sides of the outer end of the right conductive sheet are respectively provided with a limiting hinge, and a positioning opening is formed in the lower end of the limiting hinge, wherein the positioning opening is clamped on the strip-shaped protruding block, and is in interference fit with the strip-shaped protruding block.

7. The 360-degree blind-angle-free position detection magnetic sensor of claim 6, wherein the lead wire on the right side wall of the plastic box is disposed between the two limiting hinges in a penetrating manner, and the lead wire is electrically connected with the right conductive sheet.

8. The 360-degree blind-angle-free position detection magnetic sensor of claim 2, wherein the front surface of the plastic box is an opening, on which is provided with sealant, wherein the suspension bracket is a frame structure with an opening in the front surface, wherein an insulating spacer is disposed between the opening of the suspension bracket and the sealant.

9. The 360-degree blind-angle-free position detection magnetic sensor of claim 8, wherein the two ends of the insulating spacer are respectively provided with a buckle plate, wherein the insulating spacer is disposed on the front surface opening of the suspension bracket, and the two buckle plates are respectively buckled at the two ends of the suspension bracket, wherein a socket matched with the right conductive sheet is disposed on the buckle plate at the right end.

10. The 360-degree blind-angle-free position detection magnetic sensor of claim 1, wherein the conductive magnetic ring is a hard magnetic ring possessing a single polarity on its outer periphery.

11. The 360-degree blind-angle-free position detection magnetic sensor of claim 2, wherein the conductive magnetic ring is a hard magnetic ring possessing a single polarity on its outer periphery.
